(19) United States
(12) Patent Application Publication
(10) Pub. No.: US 2025/0392314 A1
(43) Pub. Date: Dec. 25, 2025

(54) JITTER IMPEDANCE DELAY LOCK LOOP

(71) Applicant: Micron Technology, Inc., Boise, ID (US)

(72) Inventor: Gyutae Park, Boise, ID (US)

(21) Appl. No.: 19/229,959

(22) Filed: Jun. 5, 2025

Related U.S. Application Data
(60) Provisional application No. 63/663,597, filed on Jun. 24, 2024.

(51) Int. Cl. H03L 7/081; G11C 7/22; H03L 7/085

(52) U.S. Cl. CPC H03L 7/0816; H03L 7/085; G11C 7/222

(57) ABSTRACT

Methods, systems, and devices for a jitter impedance delay lock loop are described. A delay lock loop circuit may be configured to align a clock signal and a data strobe signal. The delay lock loop circuit may include a variable delay component configured to receive the clock signal and output an aligned clock signal. The delay lock loop circuit may include a phase detector configured to determine whether the clock signal is aligned with the data strobe signal and output an indication to increase or decrease a delay to the clock signal. The variable delay component may increase or decrease the delay based on the indication from the phase detector. The delay lock loop circuit may include a control component configured to restrict the increase or decrease of the delay such that the delay does not exceed a threshold.

### CROSS REFERENCE

The present application for patent claims priority to U.S. Patent Application No. 63/663,597 by Park, entitled “JITTER IMPEDANCE DELAY LOCK LOOP,” filed Jun. 24, 2024, which is assigned to the assignee hereof, and which is expressly incorporated by reference in its entirety herein.

### TECHNICAL FIELD

The following relates to one or more systems for memory, including jitter impedance delay lock loop.

### BACKGROUND

Memory devices are used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored by the memory cell. To store information, a memory device may write (e.g., program, set, assign) states to the memory cells. To access stored information, a memory device may read (e.g., sense, detect, retrieve, determine) states from the memory cells.

### BRIEF DESCRIPTION OF THE DRAWINGS

FIG. 1 shows an example of a system that supports jitter impedance delay lock loop in accordance with examples as disclosed herein.

FIG. 2 shows an example of a delay lock loop circuit that supports jitter impedance delay lock loop in accordance with examples as disclosed herein.

FIG. 3 shows a block diagram of a delay lock loop circuit that supports jitter impedance delay lock loop in accordance with examples as disclosed herein.

FIG. 4 shows a flowchart illustrating a method or methods that support jitter impedance delay lock loop in accordance with examples as disclosed herein.

### DETAILED DESCRIPTION

A memory device may use (e.g., receive) a clock signal for aligning various operations of the memory device in time. For example, the clock signal may be an oscillating reference signal used to coordinate the timing of various components of the memory device. In some cases, the memory device may implement a delay lock loop (DLL) circuit configured to align a data strobe signal with a clock signal, where the data strobe signal is an oscillating signal associated with communicating data between the memory device and a host device. For example, a data path associated with the data strobe signal may introduce delay into the clock signal relative to the data strobe signal, such that the clock signal may be misaligned from the data strobe signal. In some cases, the DLL circuit may be configured to add or remove a delay to the clock signal, such that the clock signal and the data strobe signal may be aligned. However, in some such cases, the DLL circuit may increase or decrease the delay to the clock signal in increments (e.g., coarse adjustments) for each loop of the clock signal through the DLL circuit, such that the resulting clock signal may jitter (e.g., bounce between being behind and ahead of the data strobe signal in time) relative to the data strobe signal. For example, the DLL circuit may detect the clock signal is behind the data strobe signal in time, and the delay to the clock signal may be increased by an increment. However, increasing the delay may cause the clock signal to be ahead of the data strobe signal in time, thus the delay to the clock signal may be decreased by an increment, causing jitter relative to the data strobe signal.

In accordance with examples as described herein, an improved DLL circuit may be configured to perform fine adjustments to the clock signal, thereby reducing jitter relative to the data strobe signal. That is, the DLL circuit may include a control component configured to restrict adjustments of the delay to the clock signal. For example, during adding the delay, the DLL circuit may increase the delay to the clock signal by an increment, however the control component may restrict the increment from exceeding a threshold associated with aligning the clock signal with the data strobe signal. Thus, the control component may prevent the clock signal from jittering relative to the data strobe signal. In some cases, implementing the control component may improve latency for outputting the clock signal due to using relatively fewer loops through the DLL circuit to adjust the delay to the clock signal. For example, because the control component may restrict the adjustments to the delay from causing jitter in the clock signal, the clock signal may not be looped through the DLL circuit a same quantity of times as when the delay is incremented (e.g., as in previous implementations), thereby reducing latency associated with aligning the clock signal with the data strobe signal.

In addition to applicability in memory systems as described herein, techniques for a jitter impedance DLL may be generally implemented to improve the performance of various electronic devices and systems (including artificial intelligence (AI) applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of electronic devices by improving synchronization between a clock signal and a data strobe signal, which may decrease processing or latency times otherwise associated with aligning the clock signal and data strobe signal, thereby improving response times and user experience, among other benefits.

Features of the disclosure are illustrated and described in the context of a system, a DLL circuit, a block diagram, and a flowchart.

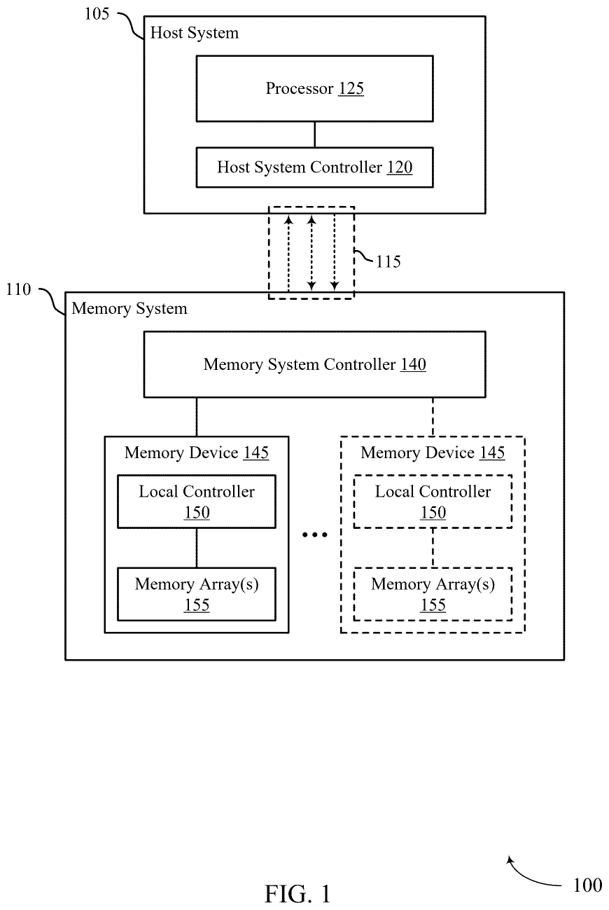

FIG. 1 illustrates an example of a system 100 that supports jitter impedance delay lock loop in accordance with examples as disclosed herein. The system 100 may include portions of an electronic device, such as a computing device, a mobile computing device, a wireless communications device, a graphics processing device, a vehicle, a smartphone, a wearable device, an internet-connected device, a vehicle controller, a system on a chip (SoC), or other stationary or portable electronic system, among other examples. The system 100 includes a host system 105, a memory system 110, and one or more channels 115 coupling the host system 105 with the memory system 110 (e.g., to support a communicative coupling). The system 100 may include any quantity of one or more memory systems 110 coupled with the host system 105.

The host system 105 may include one or more components (e.g., circuitry, processing circuitry, one or more processing components) that use memory to execute processes, any one or more of which may be referred to as or be included in a processor 125. The processor 125 may include at least one of one or more processing elements that may be co-located or distributed, including a general-purpose processor, a digital signal processor (DSP), an application-specific integrated circuit (ASIC), a field-programmable gate array (FPGA) or other programmable logic device, a controller, discrete gate or transistor logic, one or more discrete hardware components, or a combination thereof. The processor 125 may be an example of a central processing unit (CPU), a graphics processing unit (GPU), a general-purpose GPU (GPGPU), or an SoC or a component thereof, among other examples.

The host system 105 may also include at least one of one or more components (e.g., circuitry, logic, instructions) that implement the functions of an external memory controller (e.g., a host system memory controller), which may be referred to as or be included in a host system controller 120. For example, a host system controller 120 may issue commands or other signaling for operating the memory system 110, such as write commands, read commands, configuration signaling or other operational signaling. In some examples, the host system controller 120, or associated functions described herein, may be implemented by or be part of the processor 125. For example, a host system controller 120 may be hardware, instructions (e.g., software, firmware), or some combination thereof implemented by the processor 125 or other component of the host system 105. In various examples, a host system 105 or a host system controller 120 may be referred to as a host.

The memory system 110 provides physical memory locations (e.g., addresses) that may be used or referenced by the system 100. The memory system 110 may include a memory system controller 140 and one or more memory devices 145 (e.g., memory packages, memory dies, memory chips) operable to store data. The memory system 110 may be configurable for operations with different types of host systems 105, and may respond to commands from the host system 105 (e.g., from a host system controller 120). For example, the memory system 110 (e.g., a memory system controller 140) may receive a write command indicating that the memory system 110 is to store data received from the host system 105, or receive a read command indicating that the memory system 110 is to provide data stored in a memory device 145 to the host system 105, or receive a refresh command indicating that the memory system 110 is to refresh data stored in a memory device 145, among other types of commands and operations.

A memory system controller 140 may include at least one of one or more components (e.g., circuitry, logic, instructions) operable to control operations of the memory system 110. A memory system controller 140 may include hardware or instructions that support the memory system 110 performing various operations, and may be operable to receive, transmit, or respond to commands, data, or control information related to operations of the memory system 110. A memory system controller 140 may be operable to communicate with one or more of a host system controller 120, one or more memory devices 145, or a processor 125. In some examples, a memory system controller 140 may control operations of the memory system 110 in cooperation with the host system controller 120, a local controller 150 of a memory device 145, or any combination thereof. Although the example of memory system controller 140 is illustrated as a separate component of the memory system 110, in some examples, aspects of the functionality of the memory system 110 may be implemented by a processor 125, a host system controller 120, at least one of one or more local controllers 150, or any combination thereof.

Each memory device 145 may include a local controller 150 and one or more memory arrays 155. A memory array 155 may be a collection of memory cells (e.g., a two-dimensional array, a three-dimensional array), with each memory cell being operable to store data (e.g., as one or more stored bits). Each memory array 155 may include memory cells of various architectures, such as random access memory (RAM) cells, dynamic RAM (DRAM) cells, synchronous dynamic RAM (SDRAM) cells, static RAM (SRAM) cells, ferroelectric RAM (FeRAM) cells, magnetic RAM (MRAM) cells, resistive RAM (RRAM) cells, phase change memory (PCM) cells, chalcogenide memory cells, not-or (NOR) memory cells, and not-and (NAND) memory cells, or any combination thereof.

A local controller 150 may include at least one of one or more components (e.g., circuitry, logic, instructions) operable to control operations of a memory device 145. In some examples, a local controller 150 may be operable to communicate (e.g., receive or transmit data or commands or both) with a memory system controller 140. In some examples, a memory system 110 may not include a memory system controller 140, and a local controller 150 or a host system controller 120 may perform functions of a memory system controller 140 described herein. In some examples, a local controller 150, or a memory system controller 140, or both may include decoding components operable for accessing addresses of a memory array 155, sense components for sensing states of memory cells of a memory array 155, write components for writing states to memory cells of a memory array 155, or various other components operable for supporting described operations of a memory system 110.

A host system 105 (e.g., a host system controller 120) and a memory system 110 (e.g., a memory system controller 140) may communicate information (e.g., data, commands, control information, configuration information, timing information) using one or more channels 115. Each channel 115 may be an example of a transmission medium that carries information, and each channel 115 may include one or more signal paths (e.g., a transmission medium, an electrical conductor, a conductive path) between terminals (e.g., nodes, pins, contacts) associated with the components of the system 100. A terminal may be an example of a conductive input or output point of a device of the system 100, and a terminal may be operable as part of a channel 115. To support communications over channels 115, a host system 105 (e.g., a host system controller 120) and a memory system 110 (e.g., a memory system controller 140) may include receivers (e.g., latches) for receiving signals, transmitters (e.g., drivers) for transmitting signals, decoders for decoding or demodulating received signals, or encoders for encoding or modulating signals to be transmitted, among other components that support signaling over channels 115, which may be included in a respective interface portion of the respective system.

A channel 115 may be dedicated to communicating one or more types of information, and channels 115 may include unidirectional channels, bidirectional channels, or both. For example, the channels 115 may include one or more command/address channels, one or more clock signal channels, one or more data channels, among other channels or combinations thereof. In some examples, a channel 115 may be configured to provide power from one system to another (e.g., from the host system 105 to the memory system 110, in accordance with a regulated voltage). In some examples, at least a subset of channels 115 may be configured in accordance with a protocol (e.g., a logical protocol, a communications protocol, an operational protocol, an industry standard), which may support configured operations of and interactions between a host system 105 and a memory system 110.

A clock signal channel may be operable to communicate one or more clock signals between the host system 105 and the memory system 110. Clock signals may oscillate between a high state and a low state, and may support coordination (e.g., in time) between operations of the host system 105 and the memory system 110. In some examples, a clock signal may provide a timing reference for operations of the memory system 110. For example, the clock signal may be used to align various operations of the memory system 110, such as coordinating the timing of various components of the memory system 110. A clock signal may be referred to as a control clock signal, a command clock signal, or a system clock signal. A system clock signal may be generated by a system clock, which may include one or more hardware components (e.g., oscillators, crystals, logic gates, transistors).

A data channel (e.g., a DQ channel) may be operable to communicate (e.g., bidirectionally) information (e.g., data, control information) between the host system 105 and the memory system 110. For example, a data channel may communicate information from the host system 105 to be written to the memory system 110, or information read from the memory system 110 to the host system 105 via a data strobe signal. The data strobe signal may be an oscillating signal associated with communicating data between the memory system 110 and the host system 105. In some examples, channels 115 may include one or more error detection code (EDC) channels. An EDC channel may be operable to communicate error detection signals, such as checksums or parity bits, which may accompany information conveyed over a data channel.

In some cases, a memory system may implement a DLL circuit configured to align a data strobe signal with a clock signal. For example, a data path associated with the data strobe signal may introduce delay into the clock signal relative to the data strobe signal, such that the clock signal may be misaligned from the data strobe signal. In some cases, the DLL circuit may be configured to add or remove a delay to the clock signal, such that the clock signal and the data strobe signal may be aligned.

In accordance with examples as described herein, the memory system 110 may implement an improved DLL circuit configured to perform fine adjustments to a clock signal, thereby reducing jitter relative to a data strobe signal. That is, the DLL circuit may include a control component configured to restrict adjustments of the delay to the clock signal. For example, during adding the delay, the DLL circuit may increase the delay to the clock signal by an increment, however the control component may restrict the increment from exceeding a threshold associated with aligning the clock signal with the data strobe signal. Thus, the control component may prevent the clock signal from jittering relative to the data strobe signal. In some cases, implementing the control component may improve latency for outputting the clock signal due to using relatively fewer loops through the DLL circuit to adjust the delay to the clock signal. For example, because the control component may restrict the adjustments to the delay from causing jitter in the clock signal, the clock signal may not be looped through the DLL circuit a same quantity of times as when the delay is incremented (e.g., as in previous implementations), thereby reducing latency associated with aligning the clock signal with the data strobe signal.

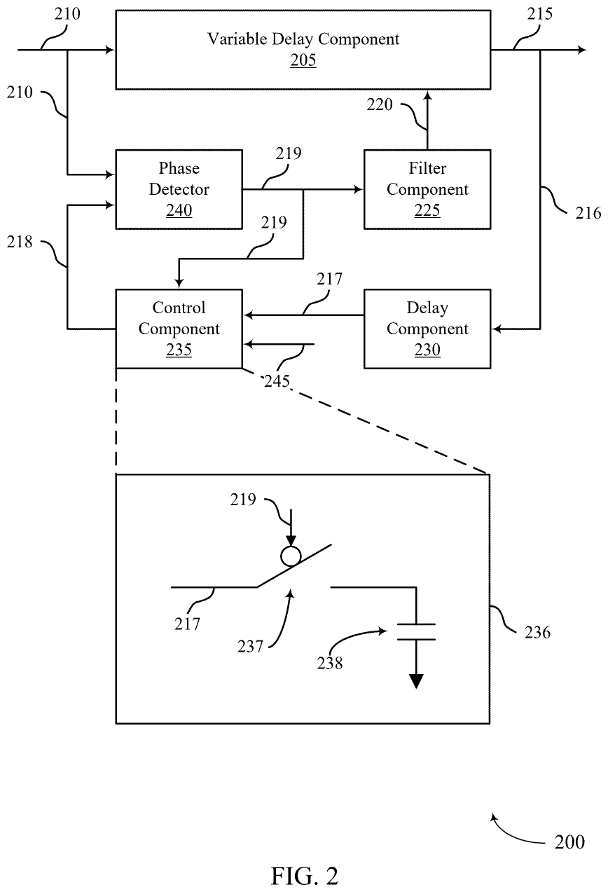

FIG. 2 shows an example of a DLL circuit 200 that supports jitter impedance delay lock loop in accordance with examples as disclosed herein. The DLL circuit 200 may illustrate aspects or operations of a system, which may be an example of a system 100, as described with reference to FIG. 1. For example, the DLL circuit 200 may be implemented at a memory system or a host system, which may be an example of a memory system 110, or a host system 105, as described with reference to FIG. 1. In some such examples, the DLL circuit 200 may be implemented within a controller of the system, which may be an example of a memory system controller 140, a host system controller 120, or a local controller 150, as described with reference to FIG. 1. In some cases, the system may implement one or more DLL circuits 200. The DLL circuit 200 may be configured to perform fine adjustments to a clock signal, thereby reducing jitter relative to a data strobe signal.

In some cases, the DLL circuit 200 may be implemented within a memory device, such as a DRAM device, coupled with the host system. The memory device may be configured to communicate data with the host system using a data strobe signal. The data strobe signal may be based on a clock signal, and the data strobe signal may be misaligned from the clock signal based on a data path associated with the data strobe signal. The DLL circuit 200 may be configured to align the clock signal and the data strobe signal, such that the memory device may communicate the data strobe signal with the memory device in reference to the clock signal.

The DLL circuit 200 may include a variable delay component 205, which may be configured to receive a clock signal 210 and output a clock signal 215. The variable delay component 205 may receive the clock signal 210 at an input terminal and output the clock signal 215 from an output terminal. In some cases, the variable delay component 205 may receive the clock signal 210 from a clock generator of the system, which may be included in the memory system or the host system. In some examples, the variable delay component 205 may be configured to receive a resulting signal 220 from a filter component 225. The variable delay component 205 may output the clock signal 215 to other components of the DLL circuit 200 for aligning the clock signal 215 with the data strobe signal. For example, the variable delay component 205 may output the clock signal 215 as a clock signal 216 to a delay component 230. In some cases, the variable delay component 205 may be configured to generate the clock signal 215 based on increasing or decreasing a delay to the clock signal 210. For example, the variable delay component 205 may receive an indication (e.g., from a phase detector 240) to increase or decrease the delay to the clock signal 210, and the variable delay component 205 may generate the clock signal 215 based on increasing or decreasing the delay. In some such cases, the variable delay component 205 may output the delayed clock signal 215 as the clock signal 216.

The DLL circuit 200 may include the delay component 230, which may be configured to receive the clock signal 216 and output a delayed clock signal 217. The delay component 230 may receive the clock signal 216 from the variable delay component 205 and output the delayed clock signal 217 to a control component 235. In some cases, the delay component 230 may be configured to add a delay to the clock signal 216, such that the delayed clock signal 217 includes the clock signal 216 with a delay. In some such cases, the delay component 230 may add the delay to the clock signal 216 based on an expected delay associated with the delays associated with a clock path of the clock signal or a data path of the data signal. In some examples, the delay added by the delay component 230 may be a static or semi-static value that is based on components of the clock tree for the clock signal 216. In some examples, the delayed clock signal 217 may generally mimic the delay associated with the data path of the data strobe signal. In some implementations, the delay to the clock signal 216 may be a fixed delay.

The DLL circuit 200 may include the control component 235, which may be configured to receive the delayed clock signal 217 and output a feedback signal 218. The control component 235 may receive the delayed clock signal 217 from the delay component 230 and output the feedback signal 218 to the phase detector 240. In some cases, the control component 235 may be configured to generate the feedback signal 218 based on modifying the delay included in the delayed clock signal 217. In some such cases, the control component 235 may be configured to restrict the increase or the decrease of the delay by the variable delay component 205. For example, the control component 235 may be configured to restrict an increase of the delay applied to the clock signal 210 by the variable delay component 205 (e.g., and output as the clock signal 216), such that the change to the delay does not exceed a threshold. Likewise, the control component 235 may be configured to restrict a decrease of the delay, such that the change to the delay does not satisfy a threshold. In other examples, the control component 235 may be configured to restrict the increase or the decrease of the delay such that the feedback signal 218 does not exceed or satisfy a threshold. In some cases, the control component 235 may be configured to restrict the increase or the decrease of the delay based on receiving an indication from the phase detector 240. In some cases, the control component 235 may be configured to receive an enable signal 245, which may enable modifying the delay. For example, the control component 235 may not restrict the increase or the decrease of the delay until receiving the enable signal 245, whereby the control component 235 may begin restricting the increase or the decrease of the delay.

The DLL circuit 200 may include a phase detector 240, which may be configured to determine whether the clock signal 210 and the feedback signal 218 are aligned in time. The phase detector 240 may receive the clock signal 210 from the clock generator of the system and may receive the feedback signal 218 from the control component 235. The phase detector 240 may compare the clock signal 210 and the feedback signal 218 to determine whether the signals are aligned in time. For example, the clock signal 210 and the feedback signal 218 may be oscillating signals, and comparing the signals may include determining whether a high oscillation of the feedback signal 218 is aligned in time with a high oscillation of the clock signal 210. In some such examples, the phase detector 240 may determine whether a rising edge of the feedback signal 218 is aligned in time with a rising edge of the clock signal 210. In some cases, the phase detector 240 may determine the feedback signal 218 is aligned with the clock signal 210, and the phase detector 240 may output the feedback signal 218 to the filter component 225. In other cases, the phase detector 240 may determine the feedback signal 218 is misaligned with the clock signal 210, and the phase detector 240 may output an indication of the misalignment to the variable delay component 205 and the control component 235. For example, the phase detector 240 may determine the feedback signal 218 is behind the clock signal 210 in time, and the phase detector 240 may output a signal 219 to the variable delay component 205 and the control component 235 indicating to increase the delay to the clock signal 210. Alternatively, the phase detector 240 may determine the feedback signal 218 is behind the clock signal 210 in time, and the phase detector 240 may output the signal 219 to the variable delay component 205 and the control component 235 indicating to decrease the delay to the clock signal 210. In some implementations, the signal 219 may be a command to increase or decrease the delay.

In some cases, control component 235 may include a subcircuit 236 configured to facilitate restricting the delay. For example, the subcircuit 236 may include at least a switch 237 (e.g., a transistor) and a capacitor 238, where the switch 237 may be configured to couple or decouple the delayed clock signal 217 received at the control component 235 with the capacitor 238. In some such examples, the capacitor 238 may be configured to increase a delay to delay clock signal 217. In some examples, the switch 237 may be configured to receive the signal 219 from the phase detector, which may indicate the control component 235 to couple or decouple the delayed clock signal 217 with the capacitor 238 to restrict the increase or the decrease of the delay.

The DLL circuit 200 may include the filter component 225, which may be configured to receive the feedback signal 218 and output the resulting signal 220. The filter component 225 may receive the feedback signal 218 from the phase detector 240 and output the resulting signal 220 to the variable delay component 205. The filter component 225 may generate the resulting signal 220 based on reducing noise associated with the feedback signal 218. For example, the filter component 225 may use a quantity of shift registers to filter noise from the feedback signal 218. In some such examples, the quantity of shift registers may filter noise from the feedback signal 218 exceeding a threshold range, such that noise from the feedback signal 218 may not exceed a lower threshold or an upper threshold. The filter component 225 may generate the resulting signal 220 based on converting the feedback signal 218 from an analog signal to a digital signal, where the digital signal may be the resulting signal 220. For example, the filter component 225 may convert analog characteristics of the feedback signal 218 to digital characteristics of the resulting signal 220.

A method for implementing the DLL circuit 200 may be described herein. During a first loop through the DLL circuit 200, the variable delay component 205 may receive the clock signal 210 and generate the clock signal 215. In some cases, generating the clock signal 215 may include applying a delay to the clock signal 210. The variable delay component 205 may output the clock signal 215 as the clock signal 216 to the delay component 230. The delay component 230 may apply a fixed delay to the clock signal 216 and output the delayed clock signal 217 to the control component 235. In some cases, because it is a first loop through the DLL circuit 200, the delay component 230 may output the delayed clock signal 217 directly through to the phase detector 240 (e.g., the control component 235 may receive the delayed clock signal 217 and output the delayed clock signal 217 to the phase detector 240), such that the control component 235 may not modify the delayed clock signal 217 to generate the feedback signal 218. In some such cases, the phase detector 240 may not receive the feedback signal 218, and may instead receive the delayed clock signal 217. In some implementations, the control component 235 may not modify the delayed clock signal 217 based on failing to receive the enable signal 245.

The phase detector 240 may compare the delayed clock signal 217 to the clock signal 210, and determine whether the delayed clock signal 217 is synchronized with the clock signal 210. In some cases, the phase detector 240 may determine the delayed clock signal 217 is synchronized with the clock signal 210, and the phase detector 240 may output the delayed clock signal 217 to the filter component 225. In some such cases, the filter component 225 may filter the delayed clock signal 217 and output the delayed clock signal 217 as the resulting signal 220 to the variable delay component 205, where the variable delay component 205 may output the delayed clock signal 217 as the clock signal 215. In other cases, the phase detector 240 may determine the delayed clock signal 217 is misaligned with the clock signal 210, and the phase detector 240 may output the delayed clock signal 217 to the filter component 225 as well as the signal 219 to the variable delay component and the control component. For example, the phase detector 240 may determine the delayed clock signal 217 is ahead of the clock signal 210, and the signal 219 may indicate to decrease the delay to the delayed clock signal 217. In another example, the phase detector 240 may determine the delayed clock signal 217 is behind the clock signal 210, and the signal 219 may indicate to increase the delay to the delayed clock signal 217. In some such cases, the filter component 225 may filter the delayed clock signal 217 and output the delayed clock signal 217 as the resulting signal 220 to the variable delay component 205, where the variable delay component 205 may initiate a second loop through the DLL circuit 200.

In some cases, during the second loop through the DLL circuit 200, the phase detector 240 may indicate to the variable delay component 205 to increase the delay to the delayed clock signal 217 via the signal 219. During the second loop through the DLL circuit 200, the variable delay component 205 may receive the delayed clock signal 217 and generate the clock signal 215. In some cases, generating the clock signal 215 may include applying a delay (e.g., another delay) to the delayed clock signal 217. For example, the variable delay component 205 may increase the delay to the delayed clock signal 217 based on receiving the signal 219 from the phase detector 240. In some such examples, the variable delay component 205 may increase the delay to the delayed clock signal 217 by an incremental increase (e.g., a standardized unit of increase). The variable delay component 205 may output the clock signal 215 as the clock signal 216 to the delay component 230. The delay component 230 may apply a fixed delay to the clock signal 216 and output a new delayed clock signal 217 to the control component 235. Because it is a second loop through the DLL circuit 200, the delay component 230 may output the delayed clock signal 217 to the control component 235. The control component 235 may receive the delayed clock signal 217 from the delay component 230 and the signal 219 from the phase detector 240, and the control component 235 may restrict the delay applied by the variable delay component 205 from increasing the delay to the delayed clock signal 217 from exceeding a threshold. In some cases, the control component 235 may restrict the delay based on applying the signal 219 to the switch 237 and activating the capacitor 238. The control component 235 may generate the feedback signal 218 based on modifying the delay to the delayed clock signal 217, and output the feedback signal 218 to the phase detector 240. In some implementations, the control component 235 may modify the delayed clock signal 217 based on receiving the enable signal 245.

The phase detector 240 may compare the feedback signal 218 to the clock signal 210, and determine whether the feedback signal 218 is synchronized with the clock signal 210. In some cases, the phase detector 240 may determine the feedback signal 218 is synchronized with the clock signal 210, and the phase detector 240 may output the feedback signal 218 to the filter component 225. In some such cases, the filter component 225 may filter the feedback signal 218 and output the feedback signal 218 as the resulting signal 220 to the variable delay component 205, where the variable delay component 205 may output the feedback signal 218 as the clock signal 215. In other cases, the phase detector 240 may determine the feedback signal 218 is misaligned with the clock signal 210, and the phase detector 240 may output the feedback signal 218 to the filter component 225 as well as the signal 219 to the variable delay component and the control component. For example, the phase detector 240 may determine the feedback signal 218 is ahead of the clock signal 210, and the signal 219 may indicate to decrease the delay to the feedback signal 218. In another example, the phase detector 240 may determine the feedback signal 218 is behind the clock signal 210, and the signal 219 may indicate to increase the delay to the feedback signal 218. In some such cases, the filter component 225 may filter the feedback signal 218 and output the feedback signal 218 as the resulting signal 220 to the variable delay component 205, where the variable delay component 205 may initiate a third loop through the DLL circuit 200.

In some cases, during the second loop through the DLL circuit 200, the phase detector 240 may indicate to the variable delay component 205 to decrease the delay to the delayed clock signal 217 via the signal 219. During the second loop through the DLL circuit 200, the variable delay component 205 may receive the delayed clock signal 217 and generate the clock signal 215. In some cases, generating the clock signal 215 may include reducing a delay (e.g., another delay) to the delayed clock signal 217. For example, the variable delay component 205 may reduce the delay to the delayed clock signal 217 based on receiving the signal 219 from the phase detector 240. In some such examples, the variable delay component 205 may reduce the delay to the delayed clock signal 217 by an incremental decrease (e.g., a standardized unit of increase). The variable delay component 205 may output the clock signal 215 as the clock signal 216 to the delay component 230. The delay component 230 may apply a fixed delay to the clock signal 216 and output a new delayed clock signal 217 to the control component 235. Because it is a second loop through the DLL circuit 200, the delay component 230 may output the delayed clock signal 217 to the control component 235. The control component 235 may receive the delayed clock signal 217 from the delay component 230 and the signal 219 from the phase detector 240, and the control component 235 may restrict the delay reduced by the variable delay component 205 from decreasing the delay to the delayed clock signal 217 from satisfying a threshold. In some cases, the control component 235 may restrict the delay based on applying the signal 219 to the switch 237 and activating the capacitor 238. The control component 235 may generate the feedback signal 218 based on modifying the delay to the delayed clock signal 217, and output the feedback signal 218 to the phase detector 240. In some implementations, the control component 235 may modify the delayed clock signal 217 based on receiving the enable signal 245.

The phase detector 240 may compare the feedback signal 218 to the clock signal 210, and determine whether the feedback signal 218 is synchronized with the clock signal 210. In some cases, the phase detector 240 may determine the feedback signal 218 is synchronized with the clock signal 210, and the phase detector 240 may output the feedback signal 218 to the filter component 225. In some such cases, the filter component 225 may filter the feedback signal 218 and output the feedback signal 218 as the resulting signal 220 to the variable delay component 205, where the variable delay component 205 may output the feedback signal 218 as the clock signal 215. In other cases, the phase detector 240 may determine the feedback signal 218 is misaligned with the clock signal 210, and the phase detector 240 may output the feedback signal 218 to the filter component 225 as well as the signal 219 to the variable delay component and the control component. For example, the phase detector 240 may determine the feedback signal 218 is ahead of the clock signal 210, and the signal 219 may indicate to decrease the delay to the feedback signal 218. In another example, the phase detector 240 may determine the feedback signal 218 is behind the clock signal 210, and the signal 219 may indicate to increase the delay to the feedback signal 218. In some such cases, the filter component 225 may filter the feedback signal 218 and output the feedback signal 218 as the resulting signal 220 to the variable delay component 205, where the variable delay component 205 may initiate a third loop through the DLL circuit 200.

In accordance with examples as described herein, the DLL circuit 200 may be configured to perform fine adjustments to the clock signal 215, such that the clock signal 215 may be aligned with the clock signal 210. That is, the clock signal 215 may be indicative of a delay associated with the data path for the data strobe signal, such that aligning the clock signal 215 with the clock signal 210 may align the data strobe signal with the clock signal 210. In some cases, implementing the control component 235 may enable the DLL circuit 200 to restrict the delay from exceeding or satisfying a threshold, which may provide support for fine adjusting the clock signal 215. In some such cases, implementing the control component 235 may prevent excess loops through the DLL circuit 200 from occurring during aligning the clock signal 215 with the clock signal 210. Thus, the DLL circuit 200 may support reduced latency for aligning the clock signal with the data strobe signal, thereby providing improved performance of the memory device implementing the DLL circuit 200.

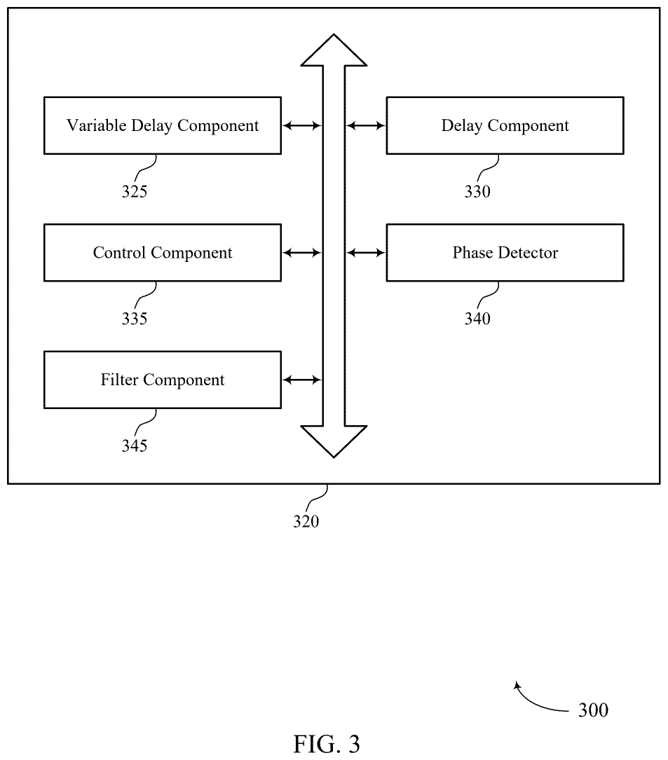

FIG. 3 shows a block diagram 300 of a delay lock loop circuit 320 that supports jitter impedance delay lock loop in accordance with examples as disclosed herein. The delay lock loop circuit 320 may be an example of aspects of a delay lock loop circuit as described with reference to FIGS. 1 through 2. The delay lock loop circuit 320, or various components thereof, may be an example of means for performing various aspects of jitter impedance delay lock loop as described herein. For example, the delay lock loop circuit 320 may include a variable delay component 325, a delay component 330, a control component 335, a phase detector 340, a filter component 345, or any combination thereof. Each of these components, or components of subcomponents thereof (e.g., one or more processors, one or more memories), may communicate, directly or indirectly, with one another (e.g., via one or more buses).

The variable delay component 325 may be configured as or otherwise support a means for receiving a first clock signal at a variable delay component and outputting a second clock signal including a first delay relative to the first clock signal. The delay component 330 may be configured as or otherwise support a means for receiving the second clock signal at a delay component coupled with the variable delay component and generating a third clock signal including the first delay relative to the first clock signal and a second delay relative to the second clock signal. The control component 335 may be configured as or otherwise support a means for receiving the third clock signal at a control component coupled with the delay component and generating a feedback signal by modifying the third clock signal. The phase detector 340 may be configured as or otherwise support a means for determining, by a phase detector coupled with the control component, whether the feedback signal is aligned with the first clock signal and outputting an indication of the alignment. In some examples, the variable delay component 325 may be configured as or otherwise support a means for adjusting, by the variable delay component, the second clock signal based at least in part on receiving the indication of the alignment.

In some examples, to support modifying the third clock signal, the control component 335 may be configured as or otherwise support a means for restricting the first delay by preventing the third clock signal from satisfying a threshold associated with a misalignment between the feedback signal and the first clock signal.

In some examples, to support modifying the third clock signal, the control component 335 may be configured as or otherwise support a means for increasing the first delay by a magnitude based at least in part on determining that the feedback signal is behind the first clock signal.

In some examples, to support modifying the third clock signal, the control component 335 may be configured as or otherwise support a means for restricting the magnitude of increasing the first delay from the first delay exceeding a second threshold.

In some examples, to support modifying the third clock signal, the control component 335 may be configured as or otherwise support a means for decreasing the first delay by a magnitude based at least in part on determining that the feedback signal is ahead of the first clock signal.

In some examples, to support modifying the third clock signal, the control component 335 may be configured as or otherwise support a means for restricting the magnitude of decreasing the first delay from the first delay satisfying a second threshold.

In some examples, modifying the third clock signal is based at least in part on the phase detector outputting the indication to the control component.

In some examples, the indication includes a command to increase the first delay or decrease the first delay.

In some examples, the phase detector 340 may be configured as or otherwise support a means for determining whether the feedback signal is aligned with the first clock signal based at least in part on modifying the third clock signal, where adjusting the second clock signal is based at least in part on determining that the feedback signal is aligned with the first clock signal.

In some examples, the phase detector 340 may be configured as or otherwise support a means for determining whether the feedback signal is aligned with the first clock signal based at least in part on modifying the third clock signal. In some examples, the control component 335 may be configured as or otherwise support a means for remodifying the third clock signal based at least in part on determining that the feedback signal is misaligned with the first clock signal, where adjusting the second clock signal is based at least in part on remodifying the third clock signal.

In some examples, the filter component 345 may be configured as or otherwise support a means for filtering the feedback signal using a plurality of shift registers to reduce noise in the feedback signal, where adjusting the second clock signal is based at least in part on filtering the feedback signal.

In some examples, to support filtering the feedback signal, the filter component 345 may be configured as or otherwise support a means for converting analog characteristics of the feedback signal to digital characteristics.

In some examples, the control component 335 may be configured as or otherwise support a means for receiving an indication to enable generating the feedback signal, where generating the feedback signal is based at least in part on receiving the indication.

In some examples, the second delay is generated to correspond to an expected delay of a memory device associated with the delay lock loop circuit.

In some examples, the described functionality of the delay lock loop circuit 320, or various components thereof, may be supported by or may refer to at least a portion of at least one processor, where such at least one processor may include one or more processing elements (e.g., a controller, a microprocessor, a microcontroller, a digital signal processor, a state machine, discrete gate logic, discrete transistor logic, discrete hardware components, or any combination of one or more of such elements). In some examples, the described functionality of the delay lock loop circuit 320, or various components thereof, may be implemented at least in part by instructions (e.g., stored in memory, non-transitory computer-readable medium) executable by such at least one processor.

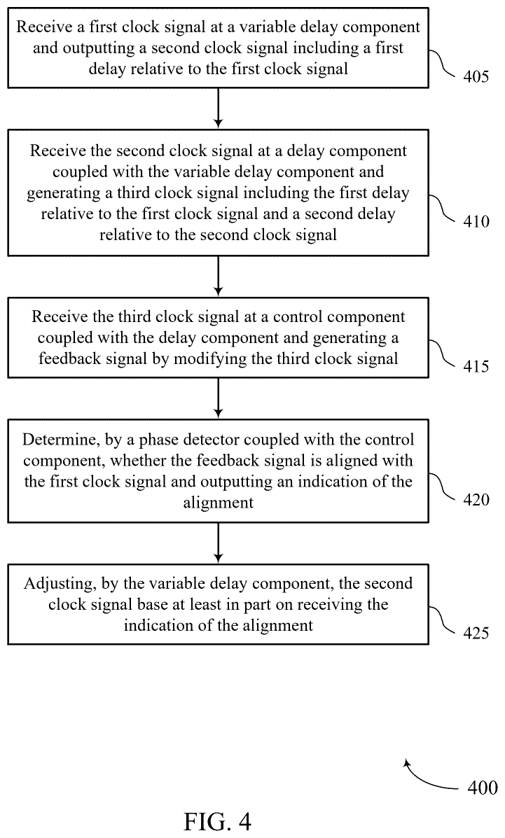

FIG. 4 shows a flowchart illustrating a method 400 that supports jitter impedance delay lock loop in accordance with examples as disclosed herein. The operations of method 400 may be implemented by a delay lock loop circuit or its components as described herein. For example, the operations of method 400 may be performed by a delay lock loop circuit as described with reference to FIGS. 1 through 3. In some examples, a delay lock loop circuit may execute a set of instructions to control the functional elements of the device to perform the described functions. Additionally, or alternatively, the delay lock loop circuit may perform aspects of the described functions using special-purpose hardware.

At 405, the method may include receiving a first clock signal at a variable delay component and outputting a second clock signal including a first delay relative to the first clock signal. In some examples, aspects of the operations of 405 may be performed by a variable delay component 325 as described with reference to FIG. 3.

At 410, the method may include receiving the second clock signal at a delay component coupled with the variable delay component and generating a third clock signal including the first delay relative to the first clock signal and a second delay relative to the second clock signal. In some examples, aspects of the operations of 410 may be performed by a delay component 330 as described with reference to FIG. 3.

At 415, the method may include receiving the third clock signal at a control component coupled with the delay component and generating a feedback signal by modifying the third clock signal. In some examples, aspects of the operations of 415 may be performed by a control component 335 as described with reference to FIG. 3.

At 420, the method may include determining, by a phase detector coupled with the control component, whether the feedback signal is aligned with the first clock signal and outputting an indication of the alignment. In some examples, aspects of the operations of 420 may be performed by a phase detector 340 as described with reference to FIG. 3.

At 425, the method may include adjusting, by the variable delay component, the second clock signal based at least in part on receiving the indication of the alignment. In some examples, aspects of the operations of 425 may be performed by a variable delay component 325 as described with reference to FIG. 3.

In some examples, an apparatus as described herein may perform a method or methods, such as the method 400. The apparatus may include features, circuitry, logic, means, or instructions (e.g., a non-transitory computer-readable medium storing instructions executable by a processor), or any combination thereof for performing the following aspects of the present disclosure:

Aspect 1: A method, apparatus, or non-transitory computer-readable medium including operations, features, circuitry, logic, means, or instructions, or any combination thereof for receiving a first clock signal at a variable delay component and outputting a second clock signal including a first delay relative to the first clock signal; receiving the second clock signal at a delay component coupled with the variable delay component and generating a third clock signal including the first delay relative to the first clock signal and a second delay relative to the second clock signal; receiving the third clock signal at a control component coupled with the delay component and generating a feedback signal by modifying the third clock signal; determining, by a phase detector coupled with the control component, whether the feedback signal is aligned with the first clock signal and outputting an indication of the alignment; and adjusting, by the variable delay component, the second clock signal based at least in part on receiving the indication of the alignment.

Aspect 2: The method, apparatus, or non-transitory computer-readable medium of aspect 1, where modifying the third clock signal includes operations, features, circuitry, logic, means, or instructions, or any combination thereof for restricting the first delay by preventing the third clock signal from satisfying a threshold associated with a misalignment between the feedback signal and the first clock signal.

Aspect 3: The method, apparatus, or non-transitory computer-readable medium of aspect 2, where modifying the third clock signal includes operations, features, circuitry, logic, means, or instructions, or any combination thereof for increasing the first delay by a magnitude based at least in part on determining that the feedback signal is behind the first clock signal.

Aspect 4: The method, apparatus, or non-transitory computer-readable medium of aspect 3, where modifying the third clock signal includes operations, features, circuitry, logic, means, or instructions, or any combination thereof for restricting the magnitude of increasing the first delay from the first delay exceeding a second threshold.

Aspect 5: The method, apparatus, or non-transitory computer-readable medium of any of aspects 2 through 4, where modifying the third clock signal includes operations, features, circuitry, logic, means, or instructions, or any combination thereof for decreasing the first delay by a magnitude based at least in part on determining that the feedback signal is ahead of the first clock signal.

Aspect 6: The method, apparatus, or non-transitory computer-readable medium of aspect 5, where modifying the third clock signal includes operations, features, circuitry, logic, means, or instructions, or any combination thereof for restricting the magnitude of decreasing the first delay from the first delay satisfying a second threshold.

Aspect 7: The method, apparatus, or non-transitory computer-readable medium of any of aspects 1 through 6, where modifying the third clock signal is based at least in part on the phase detector outputting the indication to the control component.

Aspect 8: The method, apparatus, or non-transitory computer-readable medium of aspect 7, where the indication includes a command to increase the first delay or decrease the first delay.

Aspect 9: The method, apparatus, or non-transitory computer-readable medium of any of aspects 1 through 8, further including operations, features, circuitry, logic, means, or instructions, or any combination thereof for determining whether the feedback signal is aligned with the first clock signal based at least in part on modifying the third clock signal, where adjusting the second clock signal is based at least in part on determining that the feedback signal is aligned with the first clock signal.

Aspect 10: The method, apparatus, or non-transitory computer-readable medium of any of aspects 1 through 9, further including operations, features, circuitry, logic, means, or instructions, or any combination thereof for determining whether the feedback signal is aligned with the first clock signal based at least in part on modifying the third clock signal and remodifying the third clock signal based at least in part on determining that the feedback signal is misaligned with the first clock signal, where adjusting the second clock signal is based at least in part on remodifying the third clock signal.

Aspect 11: The method, apparatus, or non-transitory computer-readable medium of any of aspects 1 through 10, further including operations, features, circuitry, logic, means, or instructions, or any combination thereof for filtering the feedback signal using a plurality of shift registers to reduce noise in the feedback signal, where adjusting the second clock signal is based at least in part on filtering the feedback signal.

Aspect 12: The method, apparatus, or non-transitory computer-readable medium of aspect 11, where filtering the feedback signal further includes operations, features, circuitry, logic, means, or instructions, or any combination thereof for converting analog characteristics of the feedback signal to digital characteristics.

Aspect 13: The method, apparatus, or non-transitory computer-readable medium of any of aspects 1 through 12, further including operations, features, circuitry, logic, means, or instructions, or any combination thereof for receiving an indication to enable generating the feedback signal, where generating the feedback signal is based at least in part on receiving the indication.

Aspect 14: The method, apparatus, or non-transitory computer-readable medium of any of aspects 1 through 13, where the second delay is generated to correspond to an expected delay of a memory device associated with the delay lock loop circuit.

It should be noted that the aspects described herein describe possible implementations, and that the operations and the steps may be rearranged or otherwise modified and that other implementations are possible. Further, portions from two or more of the methods may be combined.

An apparatus is described. The following provides an overview of aspects of the apparatus as described herein:

Aspect 15: A delay lock loop circuit, including: a variable delay component configured to receive a first clock signal at an input terminal and generate a second clock signal including a first delay relative to the first clock signal; a delay component coupled with the variable delay component and configured to receive the second clock signal and generate a third clock signal including the first delay relative to the first clock signal and a second delay relative to the second clock signal; a control component coupled with the delay component and configured to receive the third clock signal and generate a feedback signal by modifying the third clock signal; and a phase detector coupled with the control component and configured to determine whether the feedback signal is aligned with the first clock signal and output an indication of the alignment, where the variable delay component is further configured to adjust the second clock signal based at least in part on receiving the indication of the alignment.

Aspect 16: The delay lock loop circuit of aspect 15, where, to modify the third clock signal, the control component is further configured to: restrict the first delay by preventing the third clock signal from satisfying a threshold associated with a misalignment between the feedback signal and the first clock signal.

Aspect 17: The delay lock loop circuit of aspect 16, where, to restrict the first delay, the control component is further configured to: restrict a magnitude of increasing the first delay from exceeding a second threshold.

Aspect 18: The delay lock loop circuit of any of aspects 16 through 17, where, to restrict the first delay, the control component is further configured to: restrict a magnitude of decreasing the first delay from satisfying a second threshold.

Aspect 19: The delay lock loop circuit of any of aspects 15 through 18, where the control component is further configured to: receive an indication to enable the control component to generate the feedback signal, where generating the feedback signal is based at least in part on receiving the indication.

Aspect 20: The delay lock loop circuit of any of aspects 15 through 19, further including: a filter component coupled with the control component and configured to use a plurality of shift registers to reduce noise in the feedback signal and adjust the second clock signal.

Aspect 21: The delay lock loop circuit of aspect 20, where the plurality of shift registers are configured convert analog characteristics of the feedback signal to digital characteristics associated with the second clock signal.

Aspect 22: The delay lock loop circuit of any of aspects 15 through 21, where modifying the third clock signal by the control component is based at least in part on the phase detector outputting the indication.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (e.g., in conductive contact with, connected with, coupled with) one another if there is any electrical path (e.g., conductive path) between the components that can, at any time, support the flow of signals (e.g., charge, current, voltage) between the components. A conductive path between components that are in electronic communication with each other (e.g., in conductive contact with, connected with, coupled with) may be an open circuit or a closed circuit based on the operation of the device that includes the connected components. A conductive path between connected components may be a direct conductive path between the components or may be an indirect conductive path that includes intermediate components, such as switches, transistors, or other components. In some examples, the flow of signals between the connected components may be interrupted for a time, for example, using one or more intermediate components such as switches or transistors.

The term “isolated” may refer to a relationship between components in which signals are not presently capable of flowing between the components. Components are isolated from each other if there is an open circuit between them. For example, two components separated by a switch that is positioned between the components are isolated from each other when the switch is open. When a component isolates two components, the component may initiate a change that prevents signals from flowing between the other components using a conductive path that previously permitted signals to flow.

The term “coupling” (e.g., “electrically coupling”) may refer to condition of moving from an open-circuit relationship between components in which signals are not presently capable of being communicated between the components (e.g., over a conductive path) to a closed-circuit relationship between components in which signals are capable of being communicated between components (e.g., over the conductive path). When a component, such as a controller, couples other components together, the component may initiate a change that allows signals to flow between the other components over a conductive path that previously did not permit signals to flow.

A switching component (e.g., a transistor) discussed herein may be a field-effect transistor (FET), and may include a source (e.g., a source terminal), a drain (e.g., a drain terminal), a channel between the source and drain, and a gate (e.g., a gate terminal). A conductivity of the channel may be controlled (e.g., modulated) by applying a voltage to the gate which, in some examples, may result in the channel becoming conductive. A switching component may be an example of an n-type FET or a p-type FET.

The description set forth herein, in connection with the appended drawings, describes example configurations and does not represent all the examples that may be implemented or that are within the scope of the claims. The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Similar components may be distinguished by following the reference label by one or more dashes and additional labeling that distinguishes among the similar components. If just the first reference label is used in the specification, the description is applicable to any one of the similar components having the same first reference label irrespective of the additional reference labels.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The descriptions and drawings are provided to enable a person having ordinary skill in the art to make or use the disclosure. Various modifications to the disclosure will be apparent to the person having ordinary skill in the art, and the techniques disclosed herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A delay lock loop circuit, comprising:
a variable delay component configured to receive a first clock signal at an input terminal and generate a second clock signal comprising a first delay relative to the first clock signal;
a delay component coupled with the variable delay component and configured to receive the second clock signal and generate a third clock signal comprising the first delay relative to the first clock signal and a second delay relative to the second clock signal;
a control component coupled with the delay component and configured to receive the third clock signal and generate a feedback signal by modifying the third clock signal; and
a phase detector coupled with the control component and configured to determine whether the feedback signal is aligned with the first clock signal and output an indication of the alignment, wherein the variable delay component is further configured to adjust the second clock signal based at least in part on receiving the indication of the alignment.

2. The delay lock loop circuit of claim 1, wherein, to modify the third clock signal, the control component is further configured to:
restrict the first delay by preventing the third clock signal from satisfying a threshold associated with a misalignment between the feedback signal and the first clock signal.

3. The delay lock loop circuit of claim 2, wherein, to restrict the first delay, the control component is further configured to:
restrict a magnitude of increasing the first delay from exceeding a second threshold.

4. The delay lock loop circuit of claim 2, wherein, to restrict the first delay, the control component is further configured to:
restrict a magnitude of decreasing the first delay from satisfying a second threshold.

5. The delay lock loop circuit of claim 1, wherein the control component is further configured to:
receive an indication to enable the control component to generate the feedback signal,
wherein generating the feedback signal is based at least in part on receiving the indication.

6. The delay lock loop circuit of claim 1, further comprising:
a filter component coupled with the control component and configured to use a plurality of shift registers to reduce noise in the feedback signal and adjust the second clock signal.

7. The delay lock loop circuit of claim 6, wherein the plurality of shift registers are configured convert analog characteristics of the feedback signal to digital characteristics associated with the second clock signal.

8. The delay lock loop circuit of claim 1,
wherein modifying the third clock signal by the control component is based at least in part on the phase detector outputting the indication.

9. A method by a delay lock loop circuit, comprising:
receiving a first clock signal at a variable delay component and outputting a second clock signal comprising a first delay relative to the first clock signal;
receiving the second clock signal at a delay component coupled with the variable delay component and generating a third clock signal comprising the first delay relative to the first clock signal and a second delay relative to the second clock signal;
receiving the third clock signal at a control component coupled with the delay component and generating a feedback signal by modifying the third clock signal;
determining, by a phase detector coupled with the control component, whether the feedback signal is aligned with the first clock signal and outputting an indication of the alignment; and
adjusting, by the variable delay component, the second clock signal based at least in part on receiving the indication of the alignment.

10. The method of claim 9, wherein modifying the third clock signal comprises:
restricting the first delay by preventing the third clock signal from satisfying a threshold associated with a misalignment between the feedback signal and the first clock signal.

11. The method of claim 10, wherein modifying the third clock signal comprises:
increasing the first delay by a magnitude based at least in part on determining that the feedback signal is behind the first clock signal.

12. The method of claim 11, wherein modifying the third clock signal comprises:
restricting the magnitude of increasing the first delay from the first delay exceeding a second threshold.

13. The method of claim 10, wherein modifying the third clock signal comprises:
decreasing the first delay by a magnitude based at least in part on determining that the feedback signal is ahead of the first clock signal.

14. The method of claim 13, wherein modifying the third clock signal comprises:
restricting the magnitude of decreasing the first delay from the first delay satisfying a second threshold.

15. The method of claim 9, wherein modifying the third clock signal is based at least in part on the phase detector outputting the indication to the control component.

16. The method of claim 15, wherein the indication comprises a command to increase the first delay or decrease the first delay.

17. The method of claim 9, further comprising:
determining whether the feedback signal is aligned with the first clock signal based at least in part on modifying the third clock signal, wherein adjusting the second clock signal is based at least in part on determining that the feedback signal is aligned with the first clock signal.

18. The method of claim 9, further comprising:
determining whether the feedback signal is aligned with the first clock signal based at least in part on modifying the third clock signal; and
remodifying the third clock signal based at least in part on determining that the feedback signal is misaligned with the first clock signal, wherein adjusting the second clock signal is based at least in part on remodifying the third clock signal.

19. The method of claim 9, further comprising:
filtering the feedback signal using a plurality of shift registers to reduce noise in the feedback signal, wherein adjusting the second clock signal is based at least in part on filtering the feedback signal.

20. The method of claim 19, wherein filtering the feedback signal further comprises:
converting analog characteristics of the feedback signal to digital characteristics.

21. The method of claim 9, further comprising:
receiving an indication to enable generating the feedback signal, wherein generating the feedback signal is based at least in part on receiving the indication.

22. The method of claim 9, wherein the second delay is generated to correspond to an expected delay of a memory device associated with the delay lock loop circuit.
